(19) United States
(12) Patent Application Publication
(10) Pub. No.: US 2013/0237046 A1
(43) Pub. Date: Sep. 12, 2013

(54) SEMICONDUCTOR PROCESS

(71) Applicants: Chien-Ting Lin, Hsinchu City (TW); Ssu-I Fu, Kaohsiung City (TW)

(72) Inventors: Chien-Ting Lin, Hsinchu City (TW); Ssu-I Fu, Kaohsiung City (TW)

(21) Appl. No.: 13/415,855

(22) Filed: Mar. 9, 2012

(51) Int. Cl. H01L 21/28

(52) U.S. Cl. 438/591; 257/E21.19

(57) ABSTRACT

A semiconductor process includes the following steps. A substrate having a first area and a second area is provided. A thick oxide layer and a dummy gate layer are formed on the substrate and in the first area and the second area. The dummy gate layer is removed to expose the thick oxide layer. The thick oxide layer in the first area is removed and then a thinner oxide layer is formed in the first area; or, the thick oxide layer in the first area is thinned down and a thinner oxide layer is therefore formed.

### BACKGROUND OF THE INVENTION

1. Field of the Invention

The present invention relates generally to a semiconductor process, and more specifically to a semiconductor process, which uses a thick oxide layer as an etching stop layer when a dummy gate layer is etched.

2. Description of the Prior Art

In integrated circuits, applied voltage to transistors in a high voltage component area is much higher than the applied voltage to transistors in a logic circuit area. Thus, thicknesses of buffer layers or dielectric layers of the transistors in the high voltage component area should be larger than the thicknesses of buffer layers or dielectric layers of the transistors in the logic circuit area.

Fabricating transistors in the high voltage component area and in the logic circuit area includes the following steps. A thick oxide layer suited for usage in transistors in the high voltage component area is formed on a substrate in the high voltage component area and in the logic circuit area. Then, the thick oxide layer in the logic circuit area is removed and a thinner oxide layer suited for usage in transistors in the logic circuit area is formed to replace the thick oxide layer. After the thick oxide layer is formed in the high voltage component area and the thinner oxide layer is formed in the logic circuit area, a polysilicon layer is formed on the oxide layer in the two areas at the same time. Thereafter, the polysilicon layer, the thick oxide layer and the thinner oxide layer are sequentially patterned. Sequential transistor processes are then performed.

The polysilicon layer in the logic circuit area is patterned by a dry etching process. Using the non-isotropic etching properties of the dry etching process, the patterned polysilicon layer can have vertical sidewalls. However, over-etching occurs when the dry etching process is performed but the thinner oxide layer is too thin to be an etching stop layer. As a result, the thinner oxide layer can not prevent the surface of the substrate from being damaged when the dry etching process is performed.

### SUMMARY OF THE INVENTION

The present invention provides a semiconductor process, which prevents a substrate, or a fin-shaped structure, from being damaged as the dummy gate layer is etched by using a thick oxide layer as an etching stop layer.

The present invention provides a semiconductor process including the following steps. A substrate having a first area and a second area is provided. A thick oxide layer and a dummy gate layer are formed on the substrate in the first area and the second area. The dummy gate layer is removed to expose the thick oxide layer. The thick oxide layer in the first area is removed. A thinner oxide layer is then formed in the first area.

The present invention provides a semiconductor process including the following steps. A substrate having a first area and a second area is provided. A thick oxide layer and a dummy gate layer are formed on the substrate in the first area and the second area. The dummy gate layer is removed to expose the thick oxide layer. The thick oxide layer in the first area is thinned down to form a thinner oxide layer.

According to the above, the present invention provides a semiconductor process, which forms and patterns a dummy gate layer right after a thick oxide layer is formed, and then removing or thinning the thick oxide layer in some areas, in order to forma thinner oxide layer. By doing this, due to the thick oxide layer being thick enough to be an etching stop layer while the dummy gate layer is patterned, a substrate below the dummy gate layer can avoid to be damaged as over-etching occurs.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-9 schematically depict cross-sectional views of a semiconductor process according to a first embodiment of the present invention.

FIG. 10 schematically depicts a cross-sectional view of a semiconductor process according to a second embodiment of the present invention.

### DETAILED DESCRIPTION

FIGS. 1-9 schematically depict cross-sectional views of a semiconductor process according to a first embodiment of the present invention. A substrate 110 is provided. The substrate 110 may be a semiconductor substrate such as a silicon substrate, a silicon containing substrate, an III-V group-on-silicon (such as GaN-on-silicon) substrate, a graphene-on-silicon substrate or a silicon-on-insulator (SOI) substrate. The substrate 110 comprises at least a first area A and a second area B. The first area A and the second area B can be electrically isolated from each other by a isolation structure 20 or physically isolated from each other by other regions or other devices, wherein the isolation structure 20 may be a shallow trench isolation structure, but it is not limited thereto. The first area A may be a logic circuit area or a core circuit area, and the second area B may be a high voltage component area or an input/output area, but it is not limited thereto. Furthermore, the substrate 110 may further include a third area or many areas, and semiconductor components desired to be formed in these areas may have thin oxide layers with different thicknesses. A thick oxide layer 120 is formed on the entire substrate 110. The thick oxide layer 120 may be formed through a thermal oxide process, for being used as a buffer layer or a dielectric layer of a transistor structure. In this embodiment, the thick oxide layer 120 is used for being a buffer layer of a transistor in the high voltage component area and the thickness of the thick oxide layer 120 may be 34 nm. In another embodiment, the thick oxide layer 120 may be used for forming another semiconductor component and the thickness of the thick oxide layer 120 depends upon the needs. A sacrificial layer such as a dummy gate layer 130 is formed on the entire thick oxide layer 120. In this embodiment, the dummy gate layer 130 is a polysilicon layer, but it is not limited thereto.

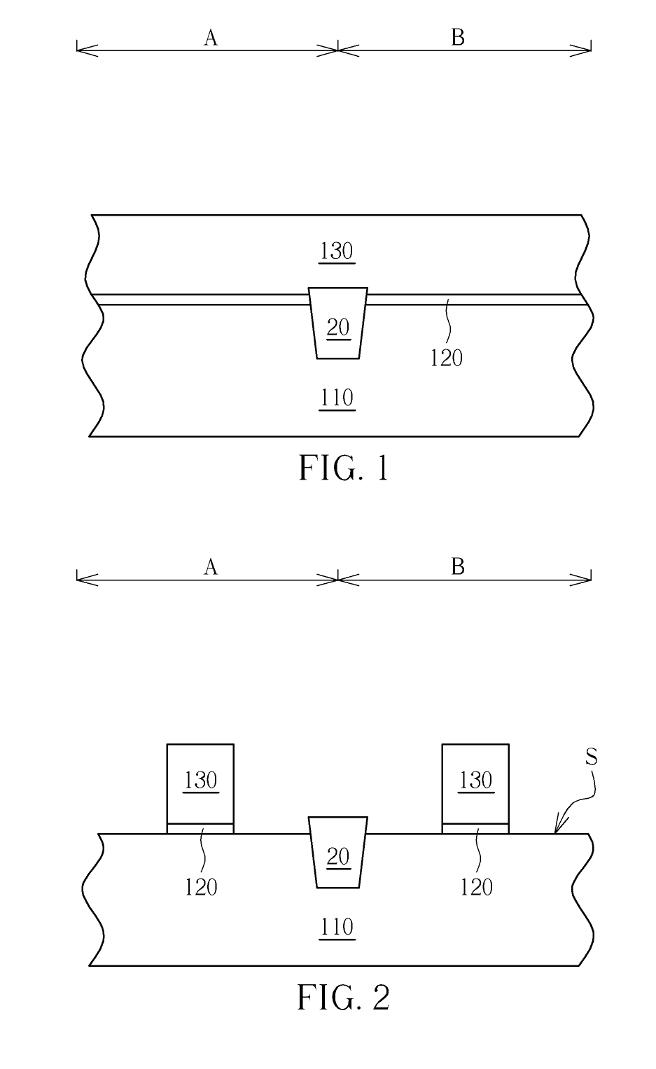

As shown in FIG. 2, the dummy gate layer 130 and the thick oxide layer 120 are patterned. More precisely, the dummy gate layer 130 is patterned by a dry etching process. Thus, the patterned dummy gate layer 130 has vertical sidewalls because of the non-isotropic etching properties of the dry etching process. Other structures formed in following processes, such as spacers, can contact the dummy gate layer 130 uniformly and smoothly, as the patterned dummy gate layer 130 has vertical sidewalls, thereby giving the formed semiconductor structure better electrical performance. Besides, the thick oxide layer 120 is used as an etching stop layer when the dummy gate layer 130 is etched by a dry etching process. Due to the thick oxide layer 120 having a thickness of 34 nm, which is suited for being used as a buffer layer in the high voltage component area, the thick oxide layer 120 is thick enough to be an etching stop layer when the dummy gate layer 130 is etched, which prevents the surface of the substrate 110 from being damaged when over-etching occurs.

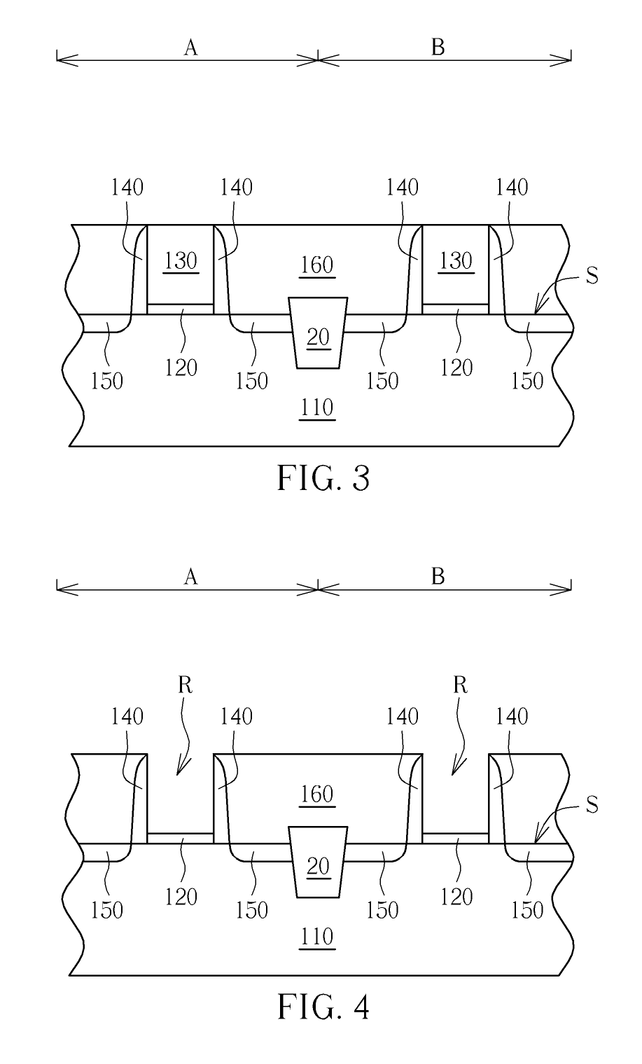

As shown in FIG. 3, a spacer 140 is formed on the substrate 110 beside the dummy gate layer 130 and the thick oxide layer 120. The spacer 140 may be a single layer or a multilayer composed of materials such as silicon nitride, silicon oxide or etc. A source/drain region 150 is formed in the substrate 110 beside the spacer 140 by processes such as an ion implantation process. An interdielectric layer 160 is formed on the substrate 110 other than the spacer 140 and the dummy gate layer 130. The interdielectric layer 160 may be an oxide layer or etc. Before the interdielectric layer 160 is formed, a contact etch stop layer (not shown) may be selectively formed. As shown in FIG. 4, the dummy gate layer 130 is removed to form two recesses R, and the thick oxide layer 120 is therefore exposed.

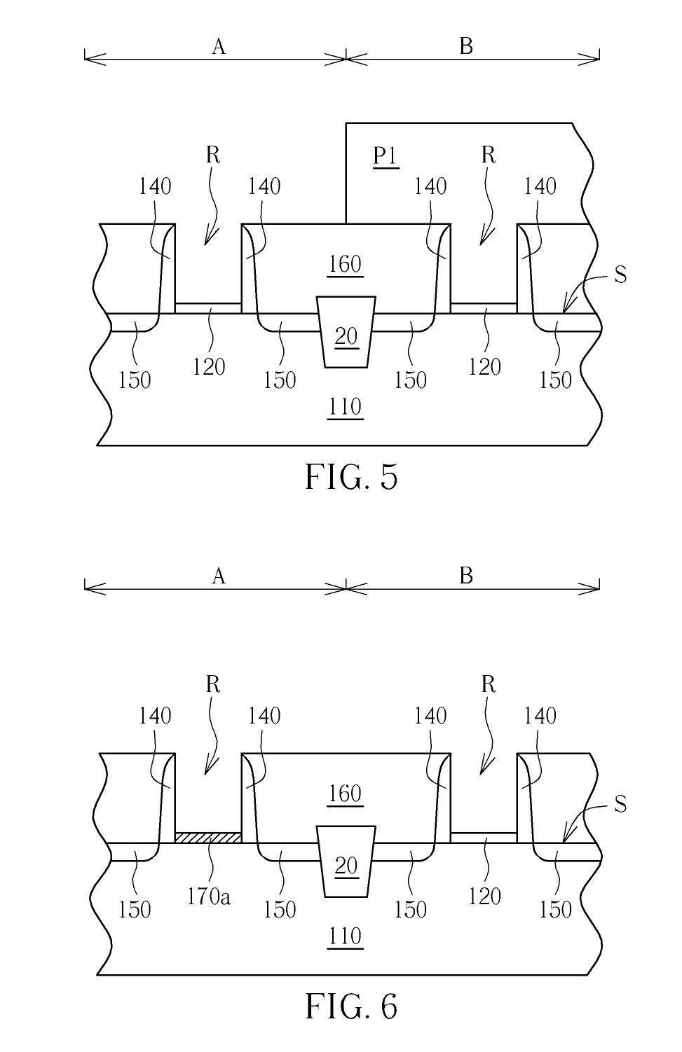

A thinner oxide layer can be formed in the first area A by the following two methods, for forming transistors suited for being used in logic circuits in the first area A. The first embodiment is shown in FIGS. 5-6 and the second embodiment is shown in FIG. 10.

### The First Embodiment

As shown in FIG. 5, the thick oxide layer 120 in the first area A is removed, wherein removing the thick oxide layer 120 may include the following steps. A mask (not shown) is formed to entirely cover the thick oxide layer 120, and then the mask (not shown) is patterned, so that the patterned mask P1 covers the thick oxide layer 120 in the second area B and exposes the thick oxide layer 120 in the first area A. The exposed thick oxide layer 120 in the first area A is removed. The thick oxide layer 120 in the first area A may be removed by a wet etching process such as a buffer oxide etch (BOE) process. The etchant of the buffer oxide etch (BOE) process may include hydrofluoric acid and fluoride ammonia mixing with different proportions, but it is not limited thereto. Then, the patterned mask P1 is removed.

As shown in FIG. 6, a thinner oxide layer 170a is formed on the substrate 110 in the first area A. In this embodiment, the thinner oxide layer 170a is formed on the substrate 110 by a chemical oxide process. The thinner oxide layer 170a has a “-”-shaped profile structure. In another embodiment, the thinner oxide layer 170a may be formed by a thermal oxide process, but it is note limited thereto.

### The Second Embodiment

After the dummy gate layer 130 is removed and two recesses R are formed to expose the thick oxide layer 120 (as shown in FIG. 4), the thick oxide layer 120 in the first area A is thinned down and a thinner oxide layer 170b is therefore formed. More precisely, as shown in FIG. 10, a mask (not shown) is formed to entirely cover the thick oxide layer 120. Then, the mask (not shown) is patterned, enabling the patterned mask P2 covering the thick oxide layer 120 in the second area B while exposing the thick oxide layer 120 in the first area A. The thick oxide layer 120 is etched back through a wet process such as a buffer oxide etch (BOE) process, and the thinner oxide layer 170b is therefore formed. Through this method, thinner oxide layers with different thicknesses can be formed in the first area A and in the second area B. Thereafter, the patterned mask P2 is removed.

According to the above, by applying the two methods (of the first embodiment and the second embodiment): (1) the thick oxide layer 120 in the first area A is entirely removed and a thinner oxide layer 170a is formed by processes such as a chemical oxide process; or, (2) the thick oxide layer 120 in the first area A is thinned down, the thinner oxide layer can be formed in the logic circuit area or in the core circuit area for forming transistors suited for the applied voltage in the logic circuit area or in the core circuit area, while the thick oxide layer 120 in the second area B is reserved in the high voltage component area or in the input/output area for forming transistors suited for the applied voltage in the high voltage component area or in the input/output area. Besides, the steps of forming the dummy gate layer 130 before the thinner oxide layer 170a and 170b is formed can prevent the substrate 110 from being damaged by over-etching as the dummy gate layer 130 is patterned.

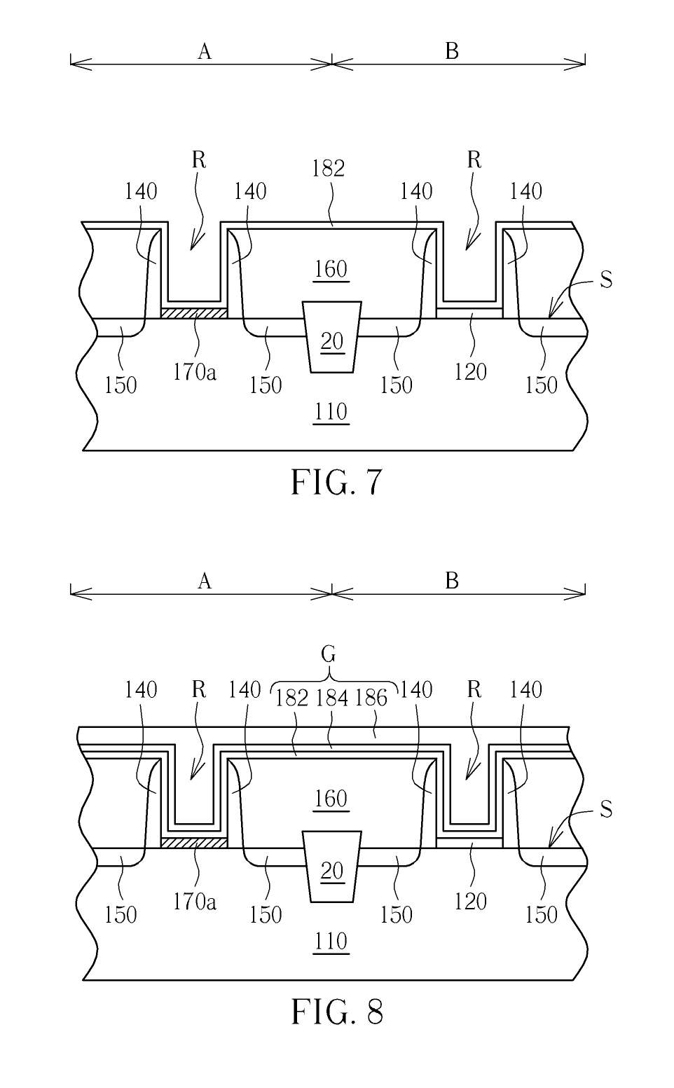

As shown in FIG. 7, a dielectric layer having a high dielectric constant 182 is formed on the thinner oxide layer 170a and 170b in the first area A or on the thick oxide layer 120 in the second area B at the same time. The dielectric layer having a high dielectric constant 182 may be the group selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalite (SrBi₂Ta₂O₉, SBT), lead zirconate titanate (PbZrₓTi₁-xO₃, PZT) and barium strontium titanate (BaₓSr₁-xTiO₃, BST). Then, a barrier layer (not shown) may be selectively formed on the dielectric layer having a high dielectric constant 182. The barrier layer (not shown) may be a single layer or a multilayer structure composed of tantalum nitride (TaN) or titanium nitride (TiN) etc.

As shown in FIG. 8, a metal gate G is formed on the dielectric layer having a high dielectric constant 182. The metal gate G may include a work function metal layer 184 formed on the dielectric layer having a high dielectric constant 182, and a low resistivity material 186 formed on the work function metal layer 184. The work function metal layer 184 may be composed of metals, which work function values meet the requirements of the transistor, and the work function metal layer 184 may be a single layer or a multilayer structure composed of titanium nitride (TiN), titanium carbide (TiC), tantalum nitride (TaN), tantalum carbide (TaC), tungsten carbide (WC), aluminum titanium (TiAl) or aluminum titanium nitride (TiAlN) etc. The low resistivity material 186 may be composed of low resistivity materials such as aluminum, copper, tungsten, aluminum titanium (TiAl) alloy, cobalt tungsten phosphide (CoWP) or etc. The metal gate G may further include a barrier layer (not shown) formed between the work function metal layer 184 and the low resistivity material 186, wherein the barrier layer (not shown) is used for preventing the work function metal layer 184 and the low resistivity material 186 from diffusing to and polluting each other. The barrier layer (not shown) may be a titanium nitride layer, but it is not limited thereto.

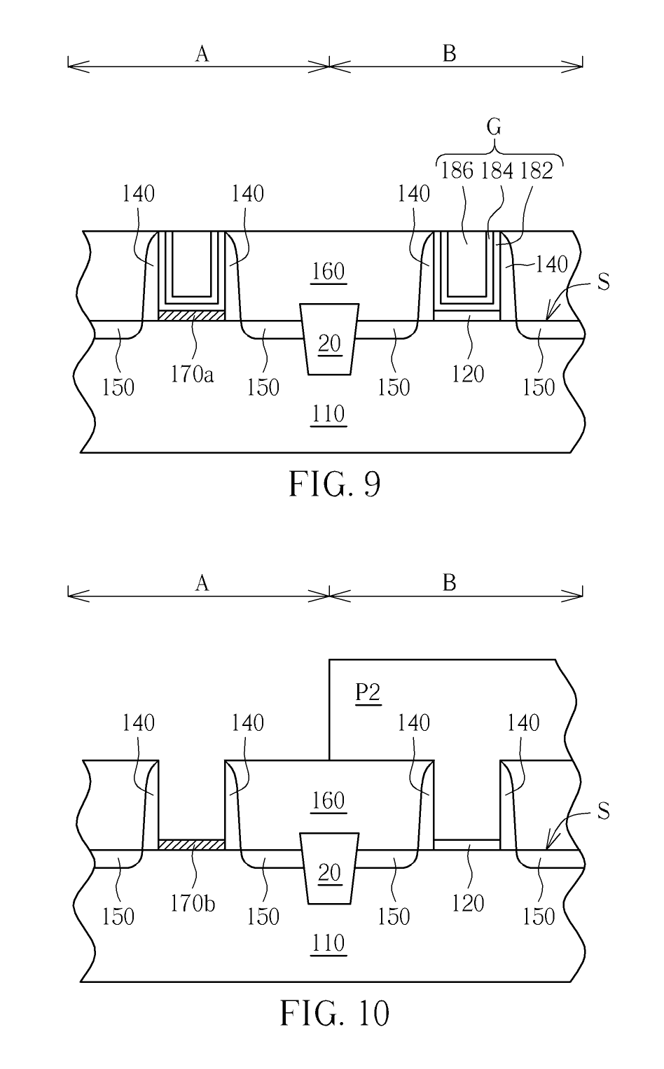

As shown in FIG. 9, the low resistivity material 186, the work function metal layer 184 and the dielectric layer having a high dielectric constant 182 are planarized by processes such as a Chemical Mechanical Polishing (CMP) process until the interdielectric layer 160 is exposed. Then, following semiconductor processes may be performed. For example, contact holes (not shown) may be etched in the interdielectric layer 160; metal plugs (not shown) may be formed in the contact holes (not shown) enabling the source/drain region 150 to connect with outer circuits.

Only planar transistors are described in the first embodiment and in the second embodiment, but the present invention can also be applied to a fin-shaped field effect transistor. Specifically, the fin-shaped field effect transistor can be formed on a fin-shaped structure. In an embodiment of the fin-shaped field effect transistor, a substrate may be divided into a first area and a second area, and two fin-shaped structures (not shown) are respectively formed in the first area and the second area. The thick oxide layer 120 and the dummy gate layer 130 just like the ones described in the first and in the second embodiment are formed on the two fin-shaped structures (not shown). The methods of forming transistors on the fin-shaped structures (not shown) are similar to those for transistor formed on the substrate in the first and the second embodiment, and are not described again. Furthermore, planar transistors are depicted in FIGS. 1-10 as described in the first and the second embodiments. However, the cross-sectional profiles of planar transistors depicted in FIGS. 1-10 are the same as the cross-sectional profiles of fin-shaped field effect transistors; therefore FIGS. 1-10 can also represent fin-shaped field effect transistors.

For simplifying the present invention, the substrate 110 in the first embodiment and the second embodiment are just divided into the first area A and the second area B, and there is just one transistor formed respectively in the two areas. In another embodiment, the first area A or the second area B may further include a plurality of transistor areas, and there may be a plurality of transistors in each of the transistor areas. For instance, as the first area A includes a plurality of transistor areas, thinner oxide layers would be formed in these transistor areas. Likewise, methods of forming the thinner oxide layers are the same as the methods of forming the thinner oxide layers in the first embodiment and the second embodiment. By doing this, thinner oxide layers can be formed respectively in these transistor areas and the thinner oxide layers may have different thicknesses.

In summary, the present invention provides a semiconductor process, which forms and patterns a dummy gate layer right after a thick oxide layer is formed, and then removes or thins the thick oxide layer in some areas (after the dummy gate layer is removed to form two recesses, exposing thereby the thick oxide layer), to form a thinner oxide layer. By doing this, the thick oxide layer is thick enough to be an etching stop layer as over-etching occurs while the dummy gate layer is patterned. Thus, a substrate below the dummy gate layer can avoid to be damaged. Specifically, after the dummy gate layer is patterned, steps of removing or thinning some areas of the thick oxide layer may include: (1) some areas of the thick oxide layer are entirely removed and then a thinner oxide layer is formed; or (2) some areas of the thick oxide layer are thinned down.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor process, comprising:
providing a substrate having a first area and a second area;
forming a thick oxide layer and a dummy gate layer on the substrate in the first area and the second area;
removing the dummy gate layer to expose the thick oxide layer;
removing the thick oxide layer in the first area; and
forming a thinner oxide layer in the first area.

2. The semiconductor process according to claim 1, wherein the first area comprises a logic circuit area or a core circuit area, and the second area comprises a high voltage component area or an input/output area.

3. The semiconductor process according to claim 1, wherein before the dummy gate layer is removed, the semiconductor process further comprises a step of patterning the dummy gate layer.

4. The semiconductor process according to claim 1, further comprising forming two fin-shaped structures respectively located in the first area and in the second area, and the thick oxide layer and the dummy gate layer are formed on the fin-shaped structures.

5. The semiconductor process according to claim 1, wherein the dummy gate layer comprises a polysilicon layer.

6. The semiconductor process according to claim 1, wherein steps of removing the thick oxide layer in the first area comprise:
forming and patterning a mask to cover the thick oxide layer in the second area; and
removing the thick oxide layer that is uncovered by the mask in the first area.

7. The semiconductor process according to claim 1, wherein the thinner oxide layer is formed by a chemical oxide process or a thermal oxide process.

8. The semiconductor process according to claim 1, further comprising:
forming a dielectric layer having a high dielectric constant and a metal gate on the thinner oxide layer in the first area and on the thick oxide layer in the second area after the thinner oxide layer is formed.

9. The semiconductor process according to claim 1, wherein the first area further comprises a plurality of transistor areas and the thinner oxide layer are respectively formed in the transistor areas.

10. The semiconductor process according to claim 9, wherein the thinner oxide layers respectively formed in the transistor areas have different thicknesses.

11. A semiconductor process, comprising:
providing a substrate having a first area and a second area;
forming a thick oxide layer and a dummy gate layer on the substrate in the first area and the second area;
removing the dummy gate layer to expose the thick oxide layer; and
thinning the thick oxide layer in the first area to form a thinner oxide layer.

12. The semiconductor process according to claim 11, wherein the first area comprises a logic circuit area or a core circuit area, and the second area comprises a high voltage component area or an input/output area.

13. The semiconductor process according to claim 11, wherein before the dummy gate layer is removed, the semiconductor process further comprises a step of patterning the dummy gate layer.

14. The semiconductor process according to claim 11, further comprising forming two fin-shaped structures located respectively in the first area and in the second area, and the thick oxide layer and the dummy gate layer are formed on the fin-shaped structures.

15. The semiconductor process according to claim 11, wherein the dummy gate layer comprises a polysilicon layer.

16. The semiconductor process according to claim 11, wherein steps of thinning the thick oxide layer in the first area comprise:
forming and patterning a mask to cover the thick oxide layer in the second area; and
thinning the thick oxide layer in the first area.

17. The semiconductor process according to claim 11, wherein the steps of thinning the thick oxide layer in the first area comprise thinning the thick oxide layer in the first area through a wet etching process.

18. The semiconductor process according to claim 11, further comprising:
forming a dielectric layer having a high dielectric constant and a metal gate on the thinner oxide layer in the first area and on the thick oxide layer in the second area after the thick oxide layer in the first area has been thinned down.

19. The semiconductor process according to claim 11, wherein the first area further comprises a plurality of transistor areas and the thinner oxide layers are respectively formed in the transistor areas.

20. The semiconductor process according to claim 19, wherein the thinner oxide layers respectively formed in the transistor areas have different thicknesses.
